(19) United States
(12) Patent Application Publication
(10) Pub. No.: US 2006/0278887 A1
(43) Pub. Date: Dec. 14, 2006

(54) White light-emitting diode and manufacturing method therefor

(75) Inventor: Jofuku Kanekiyo, Kyoto-city (JP)

Correspondence Address: STAAS & HALSEY LLP, SUITE 700, 1201 NEW YORK AVENUE, N.W., WASHINGTON, DC, 20005, US

(73) Assignee: Toshio Itakura, Tokyo (JP)

(21) Appl. No.: 11/257,115

(22) Filed: Oct. 25, 2005

(30) Foreign Application Priority Data
Jun. 13, 2005 (JP) 2005-172421

(51) Int. Cl. H01L 33/00

(52) U.S. Cl. 257/100

(57) ABSTRACT

The present invention relates to a white light-emitting diode which emits white light by combining a blue light emitted from a light-emitting diode chip for emitting the blue light, with a light that is emitted through being excited by the blue light emitted from the light-emitting diode chip; and a manufacturing method therefor: and provides a white light-emitting diode which reproduces white light in a wide range while securing equal luminescent brightness to a light-emitting diode using a conventional YAG fluophor; and a manufacturing method therefor. The white light-emitting diode has a fluophor prepared by blending two fluorescent materials of a first fluorescent material which emits yellowish green light through being excited by the blue light emitted from the light-emitting diode chip, and a second fluorescent material which emits red light through being excited by the blue light emitted from the light-emitting diode chip.

### BACKGROUND OF THE INVENTION

1. Field of the Invention

The present invention relates to a white light-emitting diode used in a backlight, a light source for lighting, a light-emitting display and various indicators, and to a manufacturing method therefor.

2. Description of the Related Art

Conventionally, a white light-emitting diode is generally composed of a light-emitting diode chip which emits blue light, and a fluophor coated thereon which is excited by one part of the blue light as an excitation source and emits yellow green or yellow light; and emits white light composed of both of the blue light by the light-emitting diode chip and the yellow green or yellow light emitted from the fluophor by excitation. Here, the white light generally means a light having intensity uniformly distributed in the wavelengths of 400 to 800 nm. Currently practically used fluophors for white light are not made of a single fluophor, but are made by blending two or more fluorescent materials into such a proper ratio as to absorb a part of an exciting light having a spectrum whose main peak exists in between 400 and 530 nm is excited by it and emit white light. However, there is only a YAG (yttrium-aluminum-garnet) fluophor as a fluophor for white light, which absorbs at least one part of blue light with wavelengths of 445 to 480 nm and emits light by excitation, under present circumstances. But, the YAG fluophor has disadvantages that the luminescent color tones are limited, and the white light-emitting diode using it reproduces a narrow range of white color. Among them, a YAG fluophor expressed by a formula (Re1-rSmr)3(Al1-sGas) 5012:Ce, in conditions of satisfying 0≦r≦1; 0≦s≦1; and that Re is at least one element selected from Y and Gd, (see, for instance, Japanese Patent No.2927279 and Japanese Patent Laid-Open No. 2003-179259) has been practically used as the fluophor for white light used with a blue light-emitting diode chip (a LED chip), from the earliest time and in a larger amount, and has contributed to industry.

On the other hand, a white light-emitting diode having the structure in which a purple and/or near-ultraviolet light-emitting diode chip excites R (Red), G (Green) and B (Blue) fluophors, has been actively studied particularly in recent years. The fluophor for white light, which is excited by purple light having short wavelengths than blue light, is more easily developed, and accordingly is currently considerably used in a market; but has disadvantages that the purple and/or near-ultraviolet light-emitting diode chip is inferior in brightness to a blue light-emitting diode chip, and accordingly that the white light-emitting diode using it has low luminous efficiency.

In the next place, a general exciting light source, the luminous principle, and the advantages and disadvantages of a currently and practically used white light-emitting diode are summarized and shown in the following Table 1.

TABLE 1

| | Exciting | | Advantages and |
|---|---|---|---|
| Method | source | Luminous principle | disadvantages |
| LED one | Blue LED + YAG | White light is | The cost is low and a power |
| chip | fluophor | obtained by exciting a | circuit is simple. |
| | | fluophor (yellow | Luminous efficiency is |
| | | light emission) with a | low. |
| | | light by a blue LED and | Color rendering |
| | | combining the blue | properties for red or the |
| | | light of the LED with | like are inadequate. |
| | | the yellow light of | |
| | | the fluophor. | |
| | Purple | White light is | Having higher conversion |
| | and/or | obtained by exciting | efficiency than YAG |
| | near- | fluophors (Red, Green | having. |
| | ultraviolet | and Blue light- | A purple and/or near- |
| | LED + R, | emission) with a light | ultraviolet LED needs to |
| | G and B | by a purple and/or | enhance its efficiency. |
| | fluophor | near-ultraviolet LED | |
| | | and combining only the | |
| | | lights emitted from | |
| | | the fluophors. | |
| LED | Blue LED + green | White light is | Having high luminous |
| Multi- | LED + red | obtained by mounting | efficiency (20 lm/w under |
| chip | LED | the LEDs of three | the present |
| | | primary colors in one | circumstances). |
| | | package. | Displayed colors can be |
| | | | freely changed. |
| | | | A power circuit is |
| | | | necessary for every LED |
| | | | chip, which is expensive. |
| | | | Color rendering |
| | | | properties are not always |
| | | | satisfactory. |

On the other hand, there has been conventionally a fluophor which absorbs at least one part of a violet light with wavelengths of 390 to 410 nm and emits light by excitation, in other words, a fluophor for white light, which simultaneously emits the lights of the three primary colors of red (R), green (G) and blue (B) by excitation, but a violet light-emitting diode chip has lower brightness (luminous intensity) than a blue light-emitting diode chip has, and the fluophor for white light is adopted only in a particular application. In addition, the violet light-emitting diode chip is also more expensive than the blue light-emitting diode chip from the viewpoint of a price.

### SUMMARY OF THE INVENTION

The present invention has been made in view of the above circumstances, provides a white light-emitting diode which reproduces white light in a wide range while securing equal luminescent brightness to a light-emitting diode using a conventional YAG fluophor, and provides a manufacturing method therefor.

A first white light-emitting diode according to the present invention, which emits white light by combining a blue light emitted from a light-emitting diode chip for emitting the blue light, with a light that is emitted through having been excited by the blue light emitted from the light-emitting diode chip, has: a fluophor including two fluorescent materials blended of a first fluorescent material which emits yellowish green light through being excited by the blue light emitted from the light-emitting diode chip, and a second fluorescent material which emits red light through being excited by the blue light emitted from the light-emitting diode chip.

Here, white light is, although not always limited to, a light having intensity uniformly distributed in the wavelengths roughly of 400 nm to 800 nm (hereafter the same). In addition, blue light has intensity in the wavelengths between 440 nm and 800 nm in a like manner, yellowish green light has intensity in wavelengths between 500 nm and 600 nm in a like manner, and red light has intensity in wavelengths between 600 nm and 700 nm in a like manner (hereafter the same).

The first white light-emitting diode according to the present invention can employ a light-emitting diode chip for emitting blue light, which has been adopted in a white light-emitting diode using a conventional YAG fluophor, and can reliably show equal luminescent brightness to the light-emitting diode using the conventional YAG fluophor. In addition, as is clear from experimental data described later, the first white light-emitting diode according to the present invention can reproduce white light in a wide range.

In addition, in a white light-emitting diode according to the present invention, it is preferable that the first fluorescent material has a composition expressed by (Y₁₋ᵣ, Gdᵣ)₃Al₅O₁₂: Ceₚ and Tb_{q},in conditions of satisfying 0<r<1, 0<p<5 and 0.5<q<5, and that the second fluorescent material has a composition expressed by ZnSe:Pb.

Now, a relationship between a peak wavelength of exciting light and wavelengths of emitted light by excitation in a conventionally well-known green light fluophor and a red light fluophor will be described.

FIG. 1 shows an excitation spectrum for and an emission spectrum from a conventionally well-known green light-emitting emitting fluophor, and FIG. 2 shows an excitation spectrum for and an emission spectrum from a conventionally well-known red light-emitting fluophor.

FIG. 1 shows spectral characteristics of a general green light-emitting fluophor which has a composition expressed by (Zn, Cd)S:Cu and Al, or ZnS:Cu, Au and Al, and emits green light by excitation. As is shown in FIG. 1, an exciting light has wavelengths of 254 to 365 nm which are the wavelengths of a purple light and has the peak in the wavelength of 330 nm (as shown in Excitation), and a peak wavelength of emitted light by adequate excitation (as shown in Emission) is 514 nm.

On the other hand, FIG. 2 shows spectral characteristics of a general red light fluophor which has a composition expressed by Y₂O₂S: Eu, and emits red light by excitation. As shown in the FIG. 2, an exciting light has wavelengths of 254 to 365 nm which are those of a purple light and has the peak in the wavelength of 330 nm, and a peak wavelength of emitted light by adequate excitation is 624 nm.

It is clear from diagrammatic drawings shown in FIGS. 1 and 2 that either of conventional general green and red fluophors is not excited by blue exciting light with wavelengths of 440 to 490 nm.

The fluophor in a white light-emitting diode according to the present invention replaces conventional general green and red fluophors, and can provide particularly a standard light D65 (quasi-daylight) for color rendering evaluation [correlated color temperature: 6500 K, and color diagram coordinate: x=0.3127 and y=0.3290]. In addition, the above fluophor can change a peak wavelength of emitted light by excitation by adjusting coefficients shown in the p and the q, and thereby can freely reproduce luminescent color tones in between yellow green and red.

In addition, the fluophor in a white light-emitting diode according to the present invention preferably contains an epoxy resin blended in addition to the first fluorescent material and the second fluorescent material; satisfies,

when a combination rate of the first fluorescent material having a composition expressed by (Y, Gd)₃Al₅O₁₂: Ce and Tb is represented by YG (%), and a combination rate of the second fluorescent material with a composition expressed by ZnSe:Pb is represented by R(%), every relationship shown in the following expressions (1) to (3):
YG+R=100(%) expression (1);
50(%)≦YG≦100(%) expression (2); and
10(%)≦R≦50(%) expression (3),
further contains, when the weight of a liquid mother resin which is either a silicone resin or a liquid epoxy resin having a base resin blended with a curing agent is determined to be 100 wt. %, a blend of the first fluorescent material and the second fluorescent material in an amount of 2.0 wt. % or more and 40 wt. % or less with respect to the liquid mother resin.

A white light-emitting diode which emits white light having a desired hue is obtained by adjusting a blending ratio of the blend to the liquid mother resin.

A second white light-emitting diode according to the present invention, which emits white light by combining a blue light emitted from a light-emitting diode chip for emitting the blue light, with a light that is emitted through having been excited by the blue light emitted from the light-emitting diode chip, includes:

a mount lead having a cup in the top;

an inner lead arranged so as to face the mount lead;

a light-emitting diode chip which emits blue light and is mounted in the cup;

an electroconductive wire for electrically connecting the inner lead with the light-emitting diode; and

a fluophor which covers the light-emitting diode chip in the cup, and is made of a blend of a first fluorescent material that emits yellowish green light through being excited by the blue light emitted from the light-emitting diode chip, a second fluorescent material that emits red light through being excited by the blue light emitted from the light-emitting diode chip, and an epoxy resin.

A method for manufacturing a white light-emitting diode according to the present invention, which emits white light by combining a blue light emitted from a light-emitting diode chip for emitting the blue light, with a light that is emitted through being excited by the blue light emitted from the light-emitting diode chip, comprises:

a mounting step of adhesively bonding the light-emitting diode chip for emitting the blue light onto a substrate having a circuit pattern thereon;

a connecting step of electrically connecting an electrode of the light-emitting diode chip adhesively bonded onto the substrate with a circuit pattern of the substrate;

a tablet-forming step of forming a fluophor into a tablet shape by applying pressure to a fluophor prepared by blending a first fluorescent material that emits yellowish green light through being excited by the blue light emitted from the light-emitting diode chip, a second fluorescent material that emits red light through being excited by the blue light emitted from the light-emitting diode chip, and a transparent epoxy resin for molding; and

a molding step of transfer-molding the fluophor of the tablet shape so as to cover the light-emitting diode chip having undergone the connecting step.

The substrate described above means a printed circuit board having various and many layers plated of a printed substrate, or a lead frame. In addition, in order to adhesively bond a light-emitting diode chip in the mounting step, an electroconductive or non-electroconductive adhesive may be used.

According to the present invention, a white light-emitting diode which reproduces white light in a wide range while securing equal luminescent brightness to a light-emitting diode using a conventional YAG fluophor can be provided, and a manufacturing method therefor can be provided.

### BRIEF DESCRIPTION OF THE DRAWINGS

FIG. 1 shows an excitation spectrum for and an emission spectrum from a conventionally well-known green light-emitting fluophor;

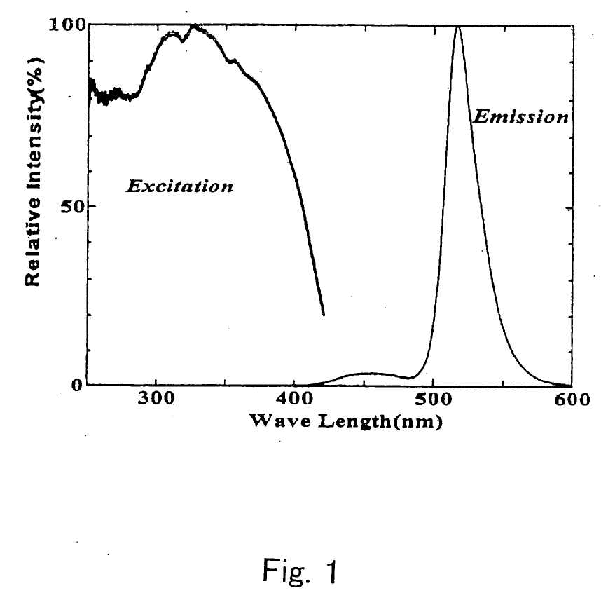

FIG. 2 shows an excitation spectrum for and an emission spectrum from a conventionally well-known red light-emitting fluophor;

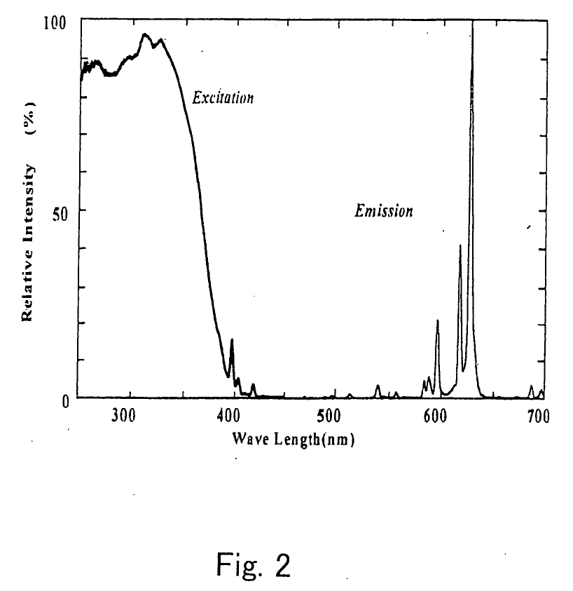

FIG. 3 is a sectional view of a white light-emitting diode of a top light-emitting type (TOP type), which corresponds to one embodiment of the white light-emitting diode according to the present invention;

FIG. 4 is a flow chart showing a method for manufacturing a white light-emitting diode shown in FIG. 3;

FIG. 5(a) shows a spectrum of an exciting light for a first fluorescent material;

FIG. 5(b) shows a spectrum of an emitted light from the first fluorescent material;

FIG. 6(a) shows a spectrum of an exciting light for a second fluorescent material;

FIG. 6(b) shows a spectrum of an emitted light from the second fluorescent material;

FIG. 7 is a CIE color diagram showing a reproducible range of white lights that are emitted from fluophors prepared by blending a first fluorescent material with a second fluorescent material in appropriate combination ratios, when they are excited by an exciting light with a wavelength of 470 nm;

FIG. 8 shows a white luminescent spectrum of a white light-emitting diode using a conventionally well-known YAG fluophor;

FIG. 9 shows an example of a white luminescent spectrum of a white light-emitting diode using a fluophor of a sample No. 6 shown in Table 2;

FIG. 10 is a sectional view of a white light-emitting diode according to the second embodiment;

FIG. 11 is a CIE color diagram showing a reproducible range of white lights that are emitted from fluophors according to the second embodiment, prepared by blending a first fluorescent material with a second fluorescent material in an appropriate blending ratio, when they are excited by an exciting light with a wavelength of 470 nm; and

FIG. 12 is a sectional view of a white light-emitting diode according to the third embodiment.

### DETAILED DESCRIPTION OF THE INVENTION

Embodiments according to the present invention will be described below with reference to the drawings.

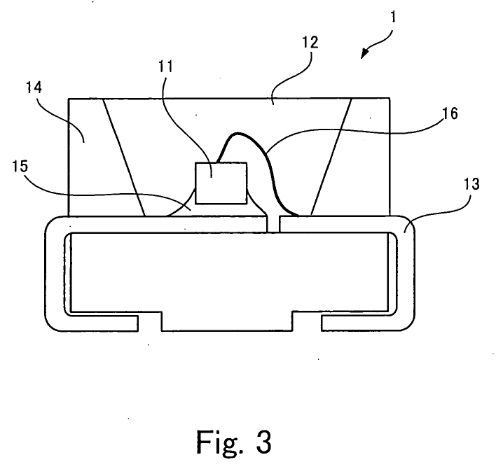

FIG. 3 is a sectional view of a white light-emitting diode of a top light-emitting type (TOP type), which corresponds to one embodiment of the white light-emitting diode according to the present invention.

A white light-emitting diode 1 shown in FIG. 3 emits white light by combining a blue light emitted from a light-emitting diode chip for emitting the blue light, with a light that is emitted through being excited by the blue light emitted from the light-emitting diode chip, and has the light-emitting diode chip 11 and a fluophor 12. The light-emitting diode chip 11 is a nitride-based compound having a GaN/SiC semiconductor structure and emits the blue light. The light-emitting diode chip 11 can employ the same light-emitting diode chip for emitting the blue light as is adopted in the white light-emitting diode using the conventional YAG fluophor, and in the white light-emitting diode according to the present embodiment, equal luminescent brightness to the white light-emitting diode using the conventional YAG fluophor is secured.

The fluophor 12 is prepared by blending a blend of two fluorescent materials of a first fluorescent material which emits yellowish green light through being excited by the blue light emitted from the light-emitting diode chip 11, and a second fluorescent material which emits red light by being excited by the blue light emitted from the light-emitting diode chip 11, with a liquid epoxy resin having a base resin blended with a curing agent, or a silicone resin [hereafter called a liquid mother resin].

The white light-emitting diode 1 shown in FIG. 3, in addition, has a lead frame 13, a housing case 14 and an electroconductive wire 16. The lead frame 13 has a plated circuit pattern.

Now, at first, a method for manufacturing the white light-emitting diode 1 will be described.

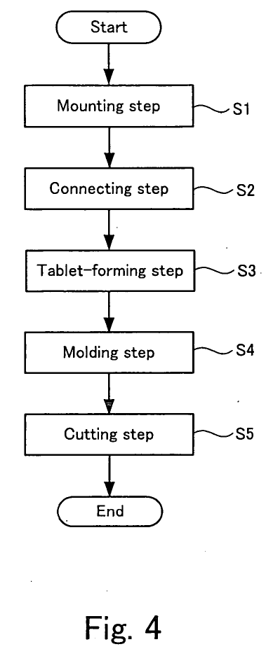

FIG. 4 is a flow chart showing a method for manufacturing the white light-emitting diode shown in FIG. 3.

At first, a mounting step (step S1) is carried out. In the mounting step, a light-emitting diode chip 11 is die-bonded onto a lead frame 13 with an adhesive of an electroconductive paste (a silver paste) 15, and is fixed there. In the step, the article is left in such a fixed temperature condition as to fit to characteristics of the adhesive to be hardened, for instance, 100 to 150° C., for 30 minutes to 1 hour.

Subsequently, a connecting step (step S2) of electrically connecting an electrode of the light-emitting diode chip 11 to a circuit pattern of a lead frame 13 with an electroconductive wire 16 is carried out.

A tablet-forming step (step S3) is also carried out. In FIG. 3, the tablet-forming step (step S3) is carried out after the connecting step has been finished, but may be carried out before the mounting step will be finished, in between the mounting step and the connecting step, or simultaneously in these steps. The tablet-forming step is a step for forming a fluophor with a tablet shape, by applying a pressure to the fluophor prepared by blending a blend of two fluorescent materials of the first and second fluorescent materials, with a liquid mother resin. Here, a liquid epoxy resin made from a transparent powdery epoxy for molding is used for the liquid mother resin.

Subsequently, a molding step (step S4) of transfer-molding a fluophor with a tablet shape is carried out, so as to cover the light-emitting diode chip 11 on which a connecting step has been finished.

Finally, a cutting step (step S5) of cutting the above product to individual products with the use of a cutter is carried out, and the all steps are finished. In the above step, the number of light-emitting diodes obtained in one transfer molding can be freely changed, according to a circuit pattern formed in a lead frame.

In the next place, the fluophor 12 will be described in detail.

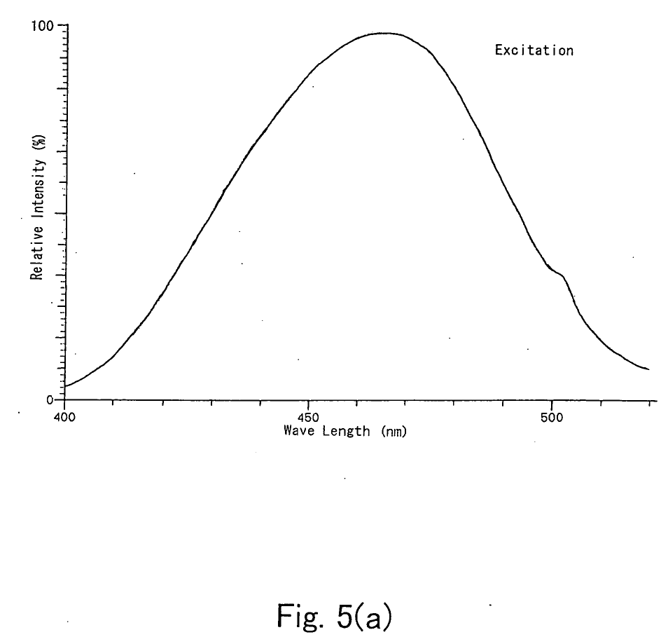

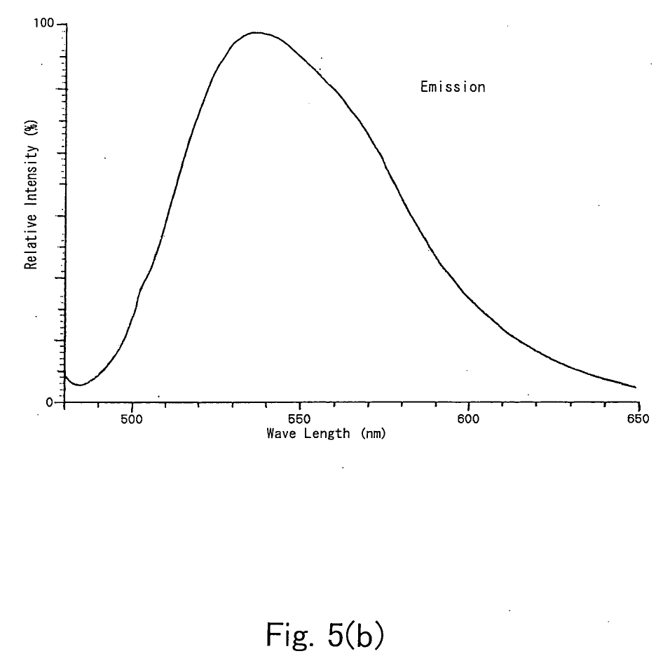

FIG. 5(a) shows a spectrum of an exciting light for a first fluorescent material, and FIG. 5(b) shows a spectrum of an emitted light from the first fluorescent material.

A first fluorescent material which emits yellowish green light by excitation is a fluophor which emits light through being excited by an exciting light having the peak in a wavelength of 466 nm, as is shown in FIG. 5(a), and accordingly emits a light in a yellowish green region having the peak in a wavelength of 536 nm as shown in FIG. 5(b) (Emission), through being excited by an exciting light in a blue region having the peak in a wavelength of 466 nm as shown in FIG. 5(a) (Excitation).

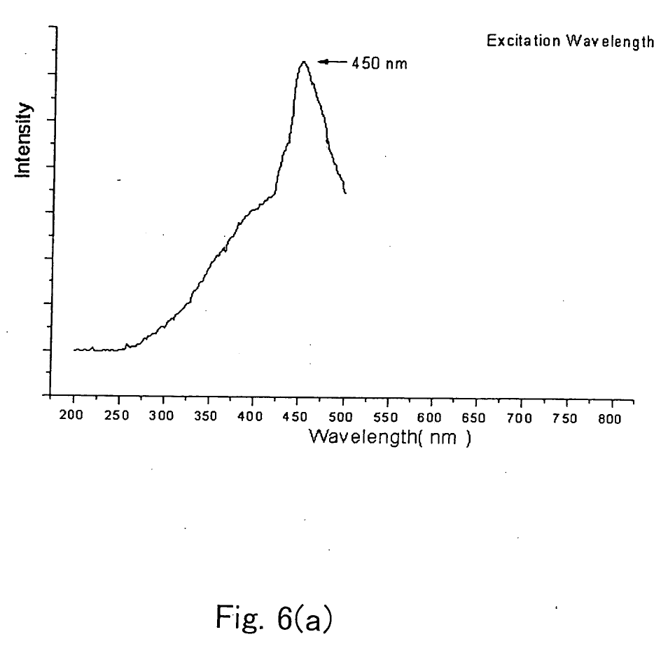

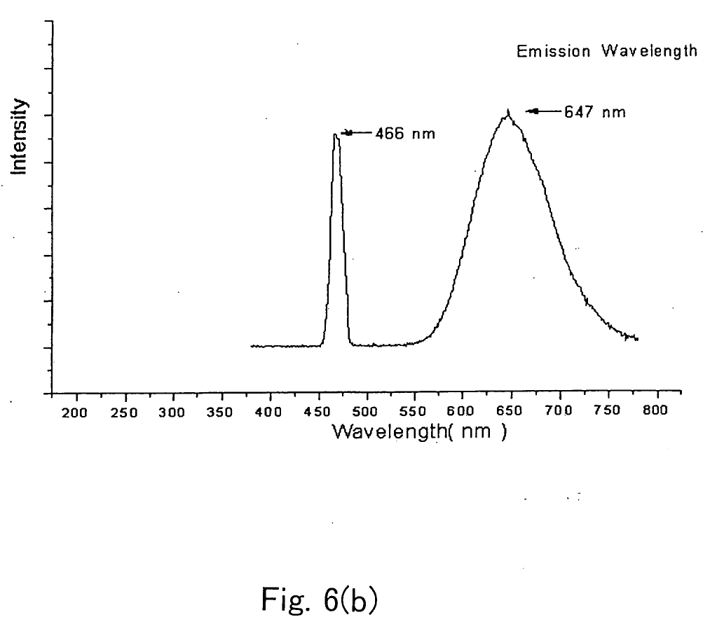

FIG. 6(a) shows a spectrum of an exciting light for a second fluorescent material, and FIG. 6(b) shows a spectrum of an emitted light from the second fluorescent material.

A second fluorescent material which emits red light by excitation is a fluophor which emits light through being excited by an exciting light having the peak in the wavelength of 450 nm, as shown in FIG. 6(a) (Excitation), and consequently emits a light in a red region having the peak in the wavelength of 647 nm as shown in FIG. 6(b) (Emission). The peak of emitted light having the wavelength of 466 nm shown in the FIG. 6(b) does not affect the emitted light.

A fluophor is prepared by blending the first fluorescent material with the second fluorescent material into a desired combination rate and blending a blend of the first fluorescent material and the second fluorescent material with a liquid mother resin at a desired combination rate.

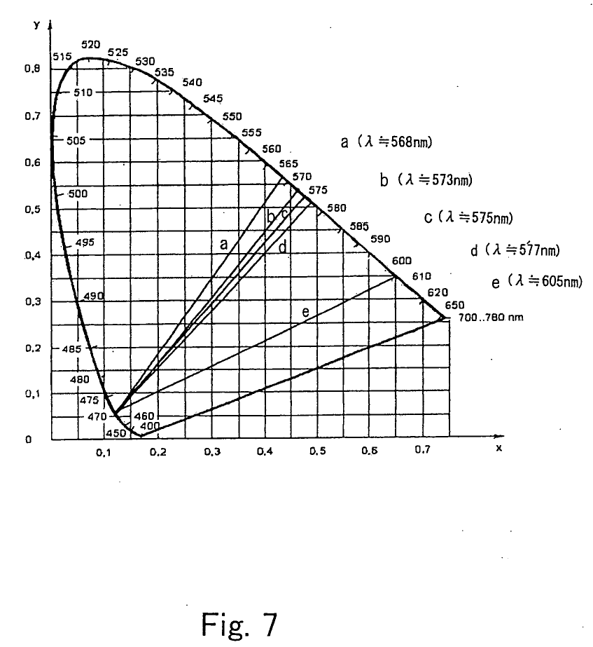

FIG. 7 is a CIE color diagram showing a reproducible range of white lights that are emitted from fluophors prepared by blending a first fluorescent material with a second fluorescent material in appropriate blending ratio, when they are excited by an exciting light with a wavelength of 470 nm.

A line (a) in FIG. 7 is a trajectory of an emitted light from a first fluorescent material having a composition expressed by (Y, Gd)₃Al₅O₁₂: Ce and Tb, when the first fluorescent material is excited by an exciting light having the wavelength of 470 nm. In addition, a line (e) is a trajectory of an emitted light from a second fluorescent material having a composition expressed by ZnSe: Pb, when the second fluorescent material is excited by the same exciting light having the wavelength of 470 nm.

In addition, lines (b) to (d) are each trajectory of an emitted light from each fluophor having a different blending ratio of a first fluorescent material and a second fluorescent material. Specifically, a line (b) is the trajectory of an emitted light from a fluophor which has been prepared by blending a blend of 85% of the first fluorescent material and 15% of a second fluorescent material, in a range between 2.0 wt. % and 10 wt. % with respect to 100 wt. % of a liquid mother resin, when the fluophor is excited by an exciting light having the wavelength of 470 nm. A line (c) is the trajectory of an emitted light from a fluophor which has been prepared by blending a blend of 80% of the first fluorescent material and 20% of the second fluorescent material, similarly in a range between 2.0 wt. % and 10 wt. % with respect to 100 wt. % of a liquid mother resin, when the fluophor is excited by an exciting light having the wavelength of 470 nm. A line (d) is the trajectory of an emitted light from a fluophor which has been prepared by blending a blend of 75% of the first fluorescent material and 25% of the second fluorescent material, similarly in a range between 2.0 wt. % and 10 wt. % with respect to.100 wt. % of a liquid mother resin, when the fluophor is excited by an exciting light having the wavelength of 470 nm.

In other words, each segment of lines (a) to (d) shows each chromaticity value changing with different blended weight ratios of a blended or single fluorescent material corresponding to each line, with respect to a liquid mother resin into which the fluorescent materials are blended.

Thus, by changing a blending ratio of a first fluorescent material and a second fluorescent material, and determining both of an absolute blending ratio of a fluorescent material to the other and a blending ratio of each blended fluophor with respect to a liquid mother resin so that the emitted light can reproduce a desired color range, desired values x and y in a CIE color diagram can be obtained.

The above description was verified by the experiment of having prepared each sample of No. 1 to 20, so that the result is shown in the following Table 2 together with a composition of a fluorescent material in each sample and a blended rate.

TABLE 2

| | | | CIE color | CIE color | Color | |
|---|---|---|---|---|---|---|
| Sample | | | diagram, | diagram, | temperature | see |
| No. | YG(%):R(%) | RP(wt %) | coordinate x | coordinate y | (K) | |
| 1 | 100:0 | 5 | 0.3135 | 0.3663 | 6,255 | line a |
| 2 | 100:0 | 10 | 0.3430 | 0.4027 | 5,194 | line a |
| 3 | 100:0 | 15 | 0.3570 | 0.4246 | 4,863 | line a |
| 4 | 100:0 | 20 | 0.3637 | 0.4288 | 4,712 | line a |
| 5 | 85:15 | 3.0 | 0.2677 | 0.2594 | 14,759 | line b |
| 6 | 85:15 | 4.0 | 0.3211 | 0.3289 | 6,070 | line b |
| 7 | 85:15 | 5.0 | 0.3227 | 0.3392 | 5,961 | line b |
| 8 | 85:15 | 6.0 | 0.3398 | 0.3542 | 5,220 | line b |
| 9 | 80:20 | 3.0 | 0.2866 | 0.2708 | 9,012 | line c |
| 10 | 80:20 | 4.0 | 0.3189 | 0.3192 | 6,249 | line c |
| 11 | 80:20 | 5.0 | 0.3468 | 0.3457 | 4,964 | line c |
| 12 | 80:20 | 6.0 | 0.3399 | 0.3434 | 5,186 | line c |
| 13 | 75:25 | 3.0 | 0.2734 | 0.2515 | 17,600 | line d |
| 14 | 75:25 | 4.0 | 0.3157 | 0.3047 | 6,560 | line d |
| 15 | 75:25 | 5.0 | 0.3392 | 0.3299 | 5,219 | line d |
| 16 | 75:25 | 6.0 | 0.3520 | 0.3413 | 4,691 | line d |
| 17 | 0:100 | 5 | 0.3916 | 0.2152 | 1,812 | line e |
| 18 | 0:100 | 10 | 0.4819 | 0.2633 | 1,393 | line e |
| 19 | 0:100 | 15 | 0.5141 | 0.2786 | 1,292 | line e |
| 20 | 0:100 | 20 | 0.5297 | 0.2895 | 1,268 | line e |

In Table 2, YG (%) means a blended ratio of (Y, Gd)₃Al₅O₁₂: Ce and Tb which is a first flourescent material, and R (%) means a blended ratio of ZnSe:Pb which is a second flourescent material (the same in Table 3 and Table 4 shown later). In addition, RP (wt. %) means a weight ratio of a blend of a first fluorescent material and a second fluorescent material with respect to 100 wt. % of an epoxy resin which is a liquid mother resin, by a weight ratio (the same in Table 3 and Table 4 shown later).

Samples No. 1 to 4 show an YG (%) of 100 and an R (%) of 0 and have values x and y of a CIE color diagram on a line (a) in FIG. 7.

On the other hand, samples No. 17 to 20 show a YG (%) of 0 and an R (%) of 100, and similarly have values x and y of a CIE color diagram on a line (e) in FIG. 7. Furthermore, when a combination rate of a first fluorescent material is represented by YG (%), and a combination rate of a second fluorescent material is represented by R (%), samples No. 5 to 16 satisfy every relationship showning the following expressions (1) to (4):
YG+R=100(%) expression (1);
50(%)≦YG≦100 (%) expression (2);
10(%)≦R≦50 (%) expression (3); and
2.0 wt. %≦RP≦40 wt. % expression (4).
Specifically, samples No. 5 to 8 have a ratio of YG (%) to R (%) of 85 to 15, have RP (wt. %) in between 3.0 wt. % and 6.0 wt. %, and can provide each CIE color diagram coordinate (x, y) on the line (b) in FIG. 7. The samples No. 6 and 7 provide values (x, y) which are in the vicinity of a color temperature around 6,000 K in the standard light D65 (quasi-daylight) of a color rendering evaluation.

In addition, samples No. 9 to 12 have a ratio of YG (%) to R (%) of 80 to 20, have RP (wt. %) in between 3.0 wt. % and 6.0 wt. %, and can provide each CIE color diagram coordinate (x, y) on the line (c) in FIG. 7.

Samples No. 13 to 16 have a blended rate of YG (%) to R (%) of 75 to 25, have RP (wt. %) in between 3.0 wt. % and 6.0 wt. %, and can provide each CIE color diagram coordinate (x, y) on the line (d) in the same figure.

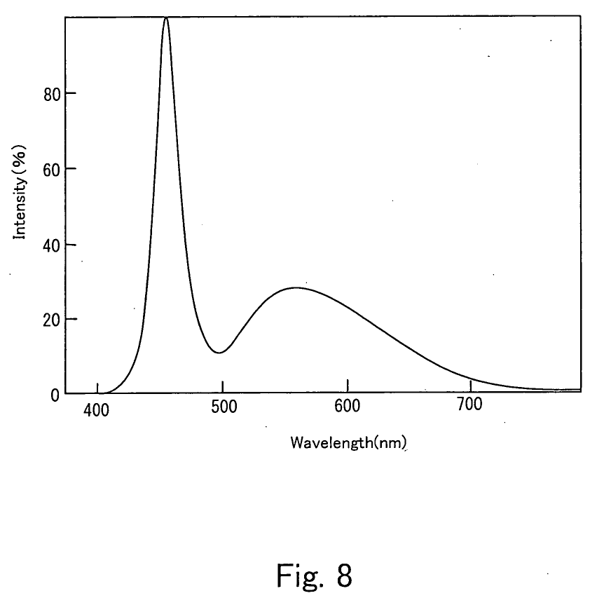

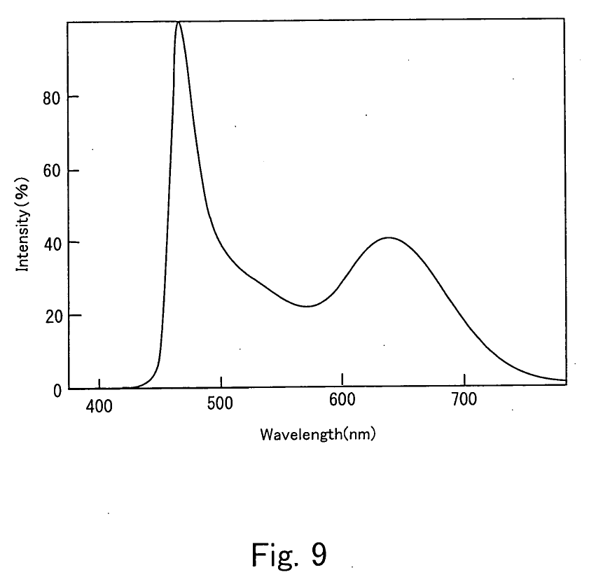

FIG. 8 and FIG. 9 show waveforms of actually measured white luminescent spectra.

FIG. 8 shows a white luminescent spectrum of a white light-emitting diode using a conventionally well-known YAG fluophor, and FIG. 9 shows an example of a white luminescent spectrum of a white light-emitting diode using a fluophor of a sample No. 6 shown in Table 2. As is clear from a comparison result between FIG. 8 and FIG. 9, the white luminescent spectrum in FIG. 9 shows higher red intensity and consequent better color rendering properties than that in FIG. 8 shows.

As is clear from the above description, the white light-emitting diode 1 according to the present embodiment can reproduce white light in a wide range, while securing equal luminescent brightness to a light-emitting diode using a conventional YAG fluophor. In addition, the white light-emitting diode 1 can acquire very close properties to a standard light D65 (quasi-daylight) for color rendering evaluation which has a color temperature: 6,000 K or less, and a color diagram coordinate: x=0.3127 and y=0.3290, by adjusting a combination rate of a first fluorescent material to a second fluorescent material and a weight ratio of a blend of the first fluorescent material and the second fluorescent material to a liquid mother resin.

Subsequently, a white light-emitting diode according to the second embodiment will be now described.

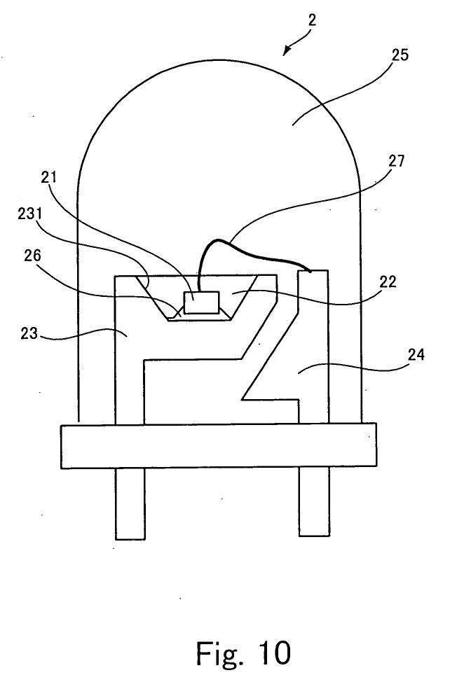

FIG. 10 is a sectional view of a white light-emitting diode according to the second embodiment.

A white light-emitting diode 2 shown in FIG. 10 has a shell shape, which corresponds to one embodiment of the second white light-emitting diode according to the present invention. The white light-emitting diode 2 also emits white light by combining a blue light emitted from a light-emitting diode chip for emitting the blue light, with a light that is emitted through being excited by the blue light emitted from the light-emitting diode chip, and has the light-emitting diode chip 21 and a fluophor 22.

The light-emitting diode chip 21 shown in FIG. 10 is a nitride-based compound having a GaN/SiC semiconductor structure, and emits blue light having emission wavelengths between 450 nm and 480 nm and the half-width of 30 nm. The light-emitting diode chip 21 also can employ the same light-emitting diode chip for emitting the blue light as is adopted in the white light-emitting diode using the conventional YAG fluophor, and the white light-emitting diode 2 according to the present embodiment also secures equal luminescent brightness to the white light-emitting diode using the conventional YAG fluophor.

In addition, the white light-emitting diode 2 shown in FIG. 10 has a mount lead 23, an inner lead 24, lens-forming resin 25 and an electroconductive wire 27. The mount lead 23 is a silver-plated metal lead frame, and has a recessed cup 231 in the top. The light-emitting diode chip 21 is die-bonded with an electroconductive paste (a silver paste) 26 in the cup 231. The electrode of the light-emitting diode chip 21 and the inner lead 24 are wire-bonded with the electroconductive wire 27 made of a gold wire with a diameter of 25 to 30 μm and are electrically connected.

The fluophor 22 covers the light-emitting diode chip 21 in the cup 231. The fluophor 22 is potted in the cup 231 in which the light-emitting diode chip 21 is placed, and is obtained through a curing reaction at a predetermined temperature for a predetermined period of time.

The lens-forming resin 25 is a translucent resin molding provided as a molding member, for the purpose of protecting the light-emitting diode chip 21. The lens-forming resin 25 is made by inserting the mount lead 23 having the inner lead 24 and the fluophor 22 potted therein, into a formwork with a shell shape, pouring the translucent resin therein, and curing it at a predetermined temperature for a predetermined period of time.

Subsequently, the fluophor 22 will be now described in detail.

The fluophor 22 shown in FIG. 10 is prepared also by blending a blend of two fluorescent materials of a first fluorescent material which emits yellowish green light through being excited by blue light emitted from the light-emitting diode chip 21, and a second fluorescent material which emits red light through being excited by the blue light emitted from the light-emitting diode chip 21, with a liquid mother resin. Now, a method for adjusting a combination rate of the first fluorescent material to the second fluorescent material and a weight ratio of the blend of first fluorescent material and the second fluorescent material to the liquid mother resin will be described.

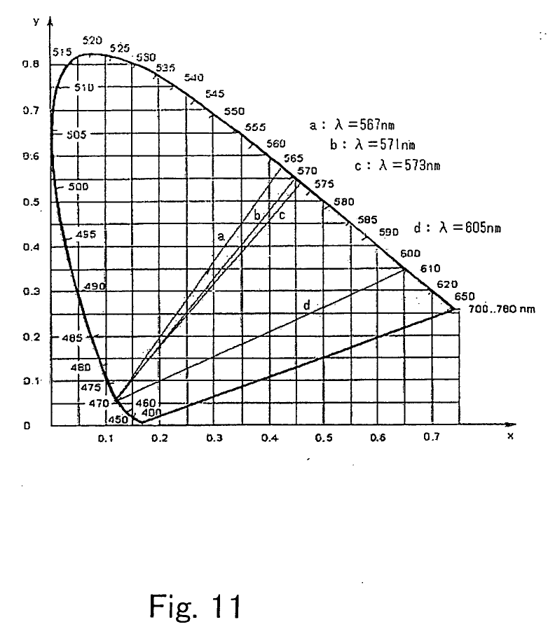

FIG. 11 is a CIE color diagram showing a reproducible range of white lights that are emitted from fluophors according to the second embodiment prepared by blending a first fluorescent material with a second fluorescent material in an appropriate blending ratio, when they are excited by an exciting light with a wavelength of 470 nm.

Here, (Y, Gd)₃Al₅O₁₂: Ce, Tb is used for a first fluorescent material and ZnSe: Pb is used for a second fluorescent material. A blend is prepared by blending two fluorescent materials of a line (a) (the first fluorescent material) and a line (d) (the second fluorescent material) shown in the CIE color diagram in FIG. 11 at a desired combination rate. Specifically, the combination rate of the first fluorescent material to the second fluorescent material is determined by a CIE color diagram coordinate x and y on any of lines (b), (c) and (d), so that the desired CIE color diagram coordinate x and y can be obtained when the blend of the fluorescent materials blended at the desired combination rate is blended with an epoxy resin at a desired combination rate. Then, by changing an absolute ratio of the bland of fluorescent materials to the epoxy resin which is the liquid mother resin, and determining the absolute ratio of each fluorescent material to the epoxy resin, so that the value x and value y can be within such a range as to reproduce a desired color, the desired value x and value y in the CIE color diagram are obtained.

The following Table 3 shows a result which has actually verified that a desired hue can be obtained, by changing a relative ratio of fluorescent materials and an absolute combination ratio of them to an epoxy resin according to the above method.

TABLE 3

| | | | CIE color | CIE color | See |
|---|---|---|---|---|---|
| | | RP | diagram, | diagram, | FIG. |
| Sample No. | YG(%):R(%) | (wt %) | coordinate x | coordinate y | 11 |
| 1 | 100:0 | 10 | 0.2080 | 0.2063 | line a |
| 2 | 100:0 | 20 | 0.2850 | 0.3495 | line a |
| 3 | 95:5 | 10 | 0.1929 | 0.1727 | line b |
| 4 | 95:5 | 20 | 0.2781 | 0.3193 | line b |
| 5 | 90:10 | 10 | 0.2028 | 0.1830 | line c |
| 6 | 90:10 | 20 | 0.2897 | 0.3153 | line c |
| 7 | 0:100 | 10 | 0.4819 | 0.2633 | line d |
| 8 | 0:100 | 20 | 0.6297 | 0.2895 | line d |

The fluophor 22 of the white light-emitting diode 2 according to the second embodiment has a thickness different from that of the fluophor 12 of the white light-emitting diode 1 according to the first embodiment. Accordingly, the white light-emitting diode 2 shows a hue different from the white light-emitting diode 1, even though they are made on the same condition, but can reproduce white light in a wide range.

Subsequently, a white light-emitting diode according to the third embodiment will be now described.

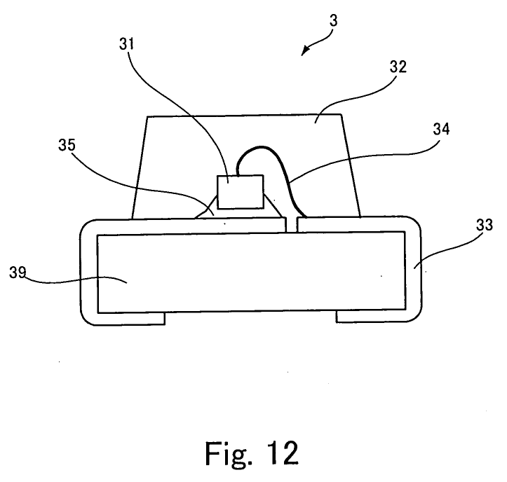

FIG. 12 is a sectional view of a white light-emitting diode according to the third embodiment.

A white light-emitting diode 3 shown in FIG. 12 is called an SMD type LED. The white light-emitting diode 3 also emits white light by combining a blue light emitted from a light-emitting diode chip for emitting the blue light, with a light that is emitted through being excited by the blue light emitted from the light-emitting diode chip, and has the light-emitting diode chip 31, a fluophor 32, a lead frame 33 and an electroconductive wire 34. FIG. 12 shows a printed circuit board 39 as well which has several layers each plated with each material into a fixed pattern.

The light-emitting diode chip 31 emits a blue light with an emission wavelength in between 450 nm and 480 nm. The light-emitting diode chip 31 also can employ the same light-emitting diode chip for emitting the blue light as is adopted in the white light-emitting diode using the conventional YAG fluophor, and the white light-emitting diode according to the present embodiment also secures equal luminescent brightness to the white light-emitting diode using the conventional YAG fluophor.

The lead frame 33 is electrically connected to the printed circuit board 39 and has a plated circuit pattern.

The white light-emitting diode 3 according to the third embodiment is also manufactured by the manufacturing method described with reference to FIG. 4. Specifically, the light-emitting diode chip 31 is adhesively bonded to a metal plated layer of the lead frame 33, with an adhesive of an electroconductive paste 35 such as a silver paste, or the like. The light-emitting diode chip 31 may be adhesively bonded to the printed circuit board 39, while skipping the lead frame 33. Then, the electrode of the light-emitting diode chip 31 is connected to the circuit pattern of the lead frame 33, with the use of the electroconductive wire 35 made of gold or aluminum.

A transparent powdery epoxy resin for transfer molding is prepared by: blending two fluorescent materials of a line (a) (a fluophor of emitting yellowish green light, which is a first fluorescent material) and a line (e) (a fluophor of emitting red light, which is a second fluorescent material), in FIG. 7, and specifically, (Y, Gd)₃Al₅O₁₂: Ce and Tb (the first fluorescent material) and ZnSe: Pb (the second fluorescent material) at a desired combination rate; and blending the blend with the epoxy resin at a desired combination rate. The fluophor 32 is prepared by: selecting the combination rate of the first fluorescent material to the second fluorescent material from lines (b), (c) and (d) in FIG. 7, so that the fluophor 32 can acquire coordinates x and y in a desired CIE color diagram; determining the coordinates x and y on the selected line in a CIE color diagram; and changing the absolute ratio of the blend of the fluorescent material to the epoxy resin according to the determined coordinates x and y.

The following Table 4 shows a result which has actually verified that a desired hue can be obtained, by changing an absolute blending ratio of a fluophor to an epoxy resin according to the above method.

TABLE 4

| | | | CIE color | CIE color |
|---|---|---|---|---|
| | | | diagram, | diagram, |
| Sample No. | YG(%):R(%) | RP (wt %) | coordinate x | coordinate y |
| 1 | 85:15 | 25 | 0.2535 | 0.2207 |
| 2 | 85:15 | 30 | 0.2790 | 0.2578 |
| 3 | 85:15 | 40 | 0.3476 | 0.3566 |
| 4 | 85:15 | 45 | 0.3755 | 0.3767 |
| 5 | 85:15 | 50 | 0.3630 | 0.3723 |
| 6 | 85:15 | 55 | 0.3718 | 0.3821 |
| 7 | 85:15 | 60 | 0.3751 | 0.3862 |

In Table 4, any of samples No. 1 to 7 employs a blend of fluorescent materials which control the ratio of YG(%):R(%) to 85:15, and obtains coordinate values x and y in a CIE color diagram, by changing a ratio RP(wt. %) of the blend with respect to a weight ratio of 100 wt. % of an epoxy resin, in a range of 25 to 60.

Thus prepared fluophor is formed into a tablet shape by applied pressure, subsequently the fluophor with the tablet shape is transfer-molded so as to cover a light-emitting diode chip 31 placed on a lead frame 33, and finally each white light-emitting diode chip is cut into individual products.

The white light-emitting diode 3 according to the third embodiment can also reproduce white light in a wide range.

In the above, three types of white light-emitting diodes were described, but the first white light-emitting diode according to the present invention can be widely applied to other types of white light-emitting diodes.

What is claimed is:

1. A white light-emitting diode which emits white light by combining a blue light emitted from a light-emitting diode chip for emitting the blue light, with a light that is emitted through having been excited by the blue light emitted from the light-emitting diode chip, the white light-emitting diode comprising:
a fluophor having two fluorescent materials blended of a first fluorescent material which emits yellowish green light through being excited by the blue light emitted from the light-emitting diode chip, and a second fluorescent material which emits red light through being excited by the blue light emitted from the light-emitting diode chip.

2. The white light-emitting diode according to claim 1, wherein the first fluorescent material has a composition expressed by (Y₁₋ᵣ, Gdᵣ)₃Al₅O₁₂: Ceₚ and Tb_{q,} in conditions of satisfying 0<r<1, 0<p<5 and 0.5<q<5, and
the second fluorescent material has a composition expressed by ZnSe:Pb.

3. The white light-emitting diode according to claim 2, wherein the fluophor further includes an epoxy resin blended in addition to the first fluorescent material and the second fluorescent material.

4. The white light-emitting diode according to claim 3, wherein the fluophor satisfies, when a combination rate of the first fluorescent material having a composition expressed by (Y, Gd)₃Al₅O₁₂: Ce and Tb is represented by YG (%), and a combination rate of the second fluorescent material with a composition expressed by ZnSe: Pb is represented by R(%), every relationship shown in the following expressions (1) to (3):
YG+R=100 (%) expression (1);
50 (%)≦YG≦100 (%) expression (2); and
10 (%)≦R≦50 (%) expression (3), and
further includes, when the weight of a liquid mother resin which is either a silicone resin or a liquid epoxy resin having a base resin blended with a curing agent is determined to be 100 wt. %, a blend of the first fluorescent material and the second fluorescent material in an amount of 2.0 wt. % or more and 40 wt. % or less with respect to the liquid mother resin.

5. A white light-emitting diode which emits white light by combining a blue light emitted from a light-emitting diode chip for emitting the blue light, with a light that is emitted through having been excited by the blue light emitted from the light-emitting diode chip, the white light-emitting diode comprising:
a mount lead having a cup in the top;
an inner lead arranged so as to face the mount lead;
a light-emitting diode chip which emits blue light and is mounted in the cup;
an electroconductive wire for electrically connecting the inner lead with the light-emitting diode; and
a fluophor which covers the light-emitting diode chip in the cup, and is made of a blend of a first fluorescent material that emits yellowish green light through being excited by the blue light emitted from the light-emitting diode chip, a second fluorescent material that emits red light through being excited by the blue light emitted from the light-emitting diode chip, and an epoxy resin.

6. A method for manufacturing a white light-emitting diode which emits white light by combining a blue light emitted from a light-emitting diode chip for emitting the blue light, with a light that is emitted through being excited by the blue light emitted from the light-emitting diode chip, comprising:
a mounting step of adhesively bonding the light-emitting diode chip for emitting the blue light onto a substrate having a circuit pattern thereon;
a connecting step of electrically connecting an electrode of the light-emitting diode chip adhesively bonded, onto the substrate with a circuit pattern of the substrate;
a tablet-forming step of forming a fluophor into a tablet shape by applying pressure to the fluophor prepared by blending a first fluorescent material that emits yellowish green light through being excited by the blue light emitted from the light-emitting diode chip, a second fluorescent material that emits red light through being excited by the blue light emitted from the light-emitting diode chip, and a transparent epoxy resin for molding; and
a molding step of transfer-molding the fluophor of the tablet shape so as to cover the light-emitting diode chip having undergone the connecting step.
